(19) United States
(12) Patent Application Publication
(10) Pub. No.: US 2008/0001790 A1
(43) Pub. Date: Jan. 3, 2008

(54) Method and system for enhancing data compression

(76) Inventors: Kyle Kirby, Anaheim, CA (US); Bill J. Kirby, Brea, CA (US)

Correspondence Address: Kyle Kirby, Suite A, 4091 E. La Palma, Anaheim, CA, 92807, US

(21) Appl. No.: 11/479,389

(22) Filed: Jun. 30, 2006

(51) Int. Cl. H03M 7/00

(52) U.S. Cl. 341/50

(57) ABSTRACT

A method and system are disclosed for enhancing the compression of a broad range of computer files through the use of a novel search-and-replace data transform process. The process involves reading an input file, converting each pair of binary bits of the input data into quarternary numeral bytes, searching the quarternary numeralized data for successive incrementing pilot strings, replacing each pilot string with the same proxy value, and outputting the proxy-substituted data to a data compression engine.

### FEDERALLY SPONSORED RESEARCH

Not Applicable

### SEQUENCE LISTING OR PROGRAM

Supplied on CD-ROM

### Background

1. Field

This invention relates generally to computer data compression, and more specifically to a method and system for enhancing compression of a broad range of computer files, also known as content-independent data compression.

2. Prior Art

Computer data comes in a variety of forms, ranging from multimedia (image and sound) data to executable programs, databases, and documents. Each of these types of data is unique in terms of their binary bit arrangements. The proliferation of computer networks coupled with the reduced cost of telecom services is resulting in a massive volume of data being generated, stored on data storage systems, and transferred over communication mediums. It is consequently becoming ever more important to employ data compression techniques in order to reduce network traffic, storage requirements, and communication costs. The particular data compression technique employed has until now depended upon the type of data that is to be compressed.

The term “data compression” refers to any process that converts data of a first given format into a second format having fewer bits than the original. Where acceptable, “lossy” data compression techniques are used where there does not exist a necessity for precise reconstruction of the original data. Some degradation of the original data occurs but greater compression ratios are achieved. “Lossless” compression refers to a data compression and decompression process in which the decompression process generates an exact replica of the original uncompressed data. For most multimedia files, lossy compression is acceptable and frequently used in order to achieve the best possible compression, since multimedia files tend to be much larger than other types of files and put the most demand on storage and communication systems. Critical documents, executable programs, and databases possess a requirement for perfect reconstruction of the original data, and in these cases, lossless compression is used.

There are many approaches to performing data compression in the prior art. A compression method known as “Huffman” encoding (see Huffman D. A., “A Method for the Construction of Minimal-Redundancy Codes”, Proceedings IRE, Vol. 40, No. 9, pp. 1098-1101, September 1952), has received considerable attention in the prior art. Huffman encoding is a type of lossless compression. In this method, it is assumed that each byte within a given data file occurs with a certain frequency. Huffman encoding works by assigning to each byte a bit string, the length of which is inversely related to its frequency. Huffman proposed an algorithm for optimally assigning the bit strings and making them uniquely decodable. In its generic form, Huffman encoding exhibits a number of limitations that make it poorly suited for real-time data transmission systems. Also, the decompression process is very complex and computationally expensive.

A second popular approach to data compression is known as “Run Length” encoding. This method is also a type of lossless compression. It encodes repeating characters in a file in a format that consists of an escape character, a repeat count, and the repeating character. All other characters in the file are encoded as plain text. The escape character is chosen as a character that is either seldom used or not found in the file being compressed. The value of Run Length encoding is highly dependent on the input file type. Run Length encoding performs well on graphical images, but has virtually no value in compressing text files, and only moderate value in compressing data files.

Another method of enhancing data compression is based on the concept of arithmetic coding. The method of arithmetic coding was suggested by Elias and presented by Abramson (see Abramson, N., “Information Theory and Coding”, McGraw-Hill, 1963). Practical implementations of Elias techniques were suggested by Rissanen (See Rissanen, J., “Generalized Kraft Inequality and Arithmetic Coding”, IBM Journal Research Development, Vol. 20, pp 198-203, May 1976), and most recently by Witten et al. (See Witten, I. H. et al., “Arithmetic Coding for Data Compression”, Communications of the ACM, Vol. 30, no. 6, pp. 520-540, June 1987). In general, arithmetic coding works by representing the source data as a fraction that assumes a value between zero and one. Recursive subdivision is performed in proportion to probabilistic estimates of the symbols in the input data. Arithmetic coding is considered by those knowledgeable in the art to be a superior compression method to most others, but it has the drawback of being computationally expensive and therefore unsuitable for real-time networking or data communications systems.

Yet another approach to data compression was developed by Ziv and Lempel, the so-called “ZL” method (see Ziv, J., and Lempel, A., “A Universal Algorithm for Sequential Data Compression”, IEEE Transactions on Information Theory, vol. IT-23, No. 3, May 1977, pp. 337-343). The ZL method and its variants, the “LZW” as introduced by Welch (see Welch, Terry A., “A Technique for High-Performance Data Compression”, IEEE Computer, pp 8-19, June 1984), are lossless, sequential encoding methods employing dictionaries (history buffers) and hashing functions. These methods are primarily limited by the available capacity of the dictionaries, and the maximum compression ratios that result are fairly modest.

Still another method of data compression is used by the commercially available Stacker LZS.TM. compressor (see U.S. Pat. No. 5,016,009). This method combines several features of the ZL method and variants, with Run Length encoding. The method is lossless and relatively computationally inexpensive, but it suffers from many of the limitations of Run Length encoding techniques. Consequently, the resulting compression ratios are very moderate.

Various other methods of data compression are based upon what is known as “lossy” encoding methods. These methods are frequently employed to compress multimedia (i.e., picture and sound) files because reproducing an exact copy of the original data is not a critical requirement. Human senses cannot detect the slight loss in signal quality upon playback resulting from lossy compression, therefore the gains in compression ratio favor their use for multimedia files.

Nonetheless, all data compression methods known in the art suffer from a number of disadvantages.
(a) The effectiveness of current compression methods are highly dependent on the type of files they compress, that is, they work well on certain types of files, but very poorly or not at all on others,
(b) There is no compression method in the current art that is equally effective at compressing every type of file,
(c) Current compression methods are slow and computationally expensive.

### Objects and Advantages

Accordingly, several objects and advantages of the present invention are:
(a) To provide a method and system of enhancing data compression whose effectiveness is not dependent on the type of data being compressed,
(b) To provide a method and system of enhancing data compression which is highly cost-effective, in that it significantly reduces bandwidth, memory, and data storage requirements,
(c) To provide a method and system of enhancing data compression with a low computational expense so that it can compress and decompress data in real-time,
(d) To provide a method and system of enhancing data compression in which the compressed data uses significantly less bandwidth, storage space, and memory than the original input data,
(e) To provide a method and system of enhancing data compression that is computationally inexpensive while achieving high compression ratios.

Still further objects and advantages will become apparent from a consideration of the ensuing description and drawings.

### SUMMARY

The present invention can be regarded as a method and system for enhancing compression and decompression of computer data. Accordingly, what is believed to be new and novel is a method and system of preparing data prior to compressing, so that it can be compressed in real time at high speed and with a low computational expense.

### DRAWINGS

### Drawing Figures

In the ensuing drawings, like reference numerals in the several figures denote like elements. In addition, closely related figures and closely related elements have the same number but different alphabetic suffixes.

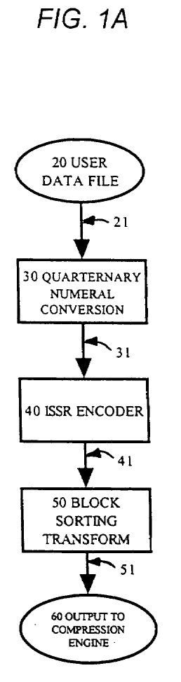

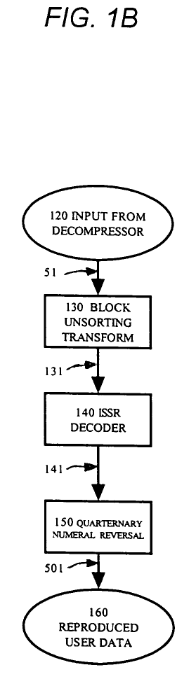

FIG. 1A is a diagram of the overall compression enhancing process of the present invention.

FIG. 1B is a diagram of the overall decompression process of the present invention.

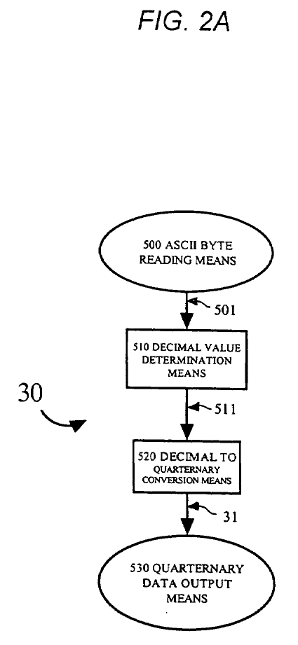

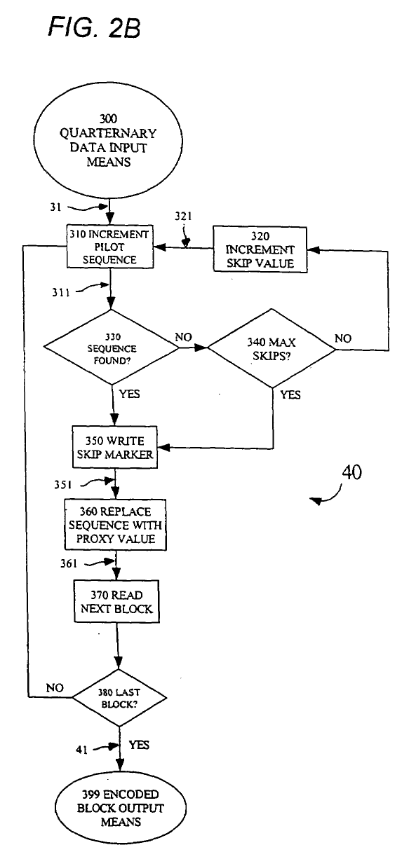

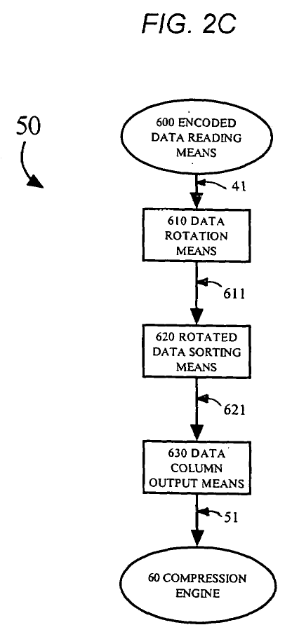

FIG. 2A is a diagram of the first compression enhancement stage of the present invention.

FIG. 2B is a diagram of the second compression enhancement stage of the present invention.

FIG. 2C is a diagram of the final compression enhancement stage of the present invention.

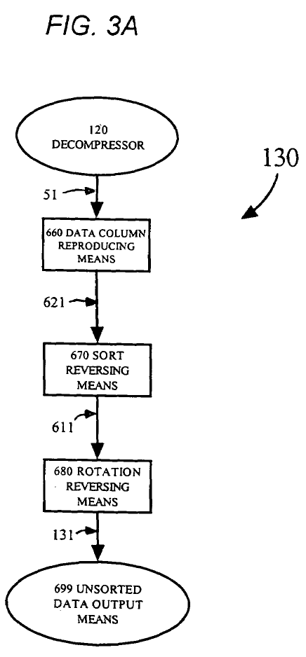

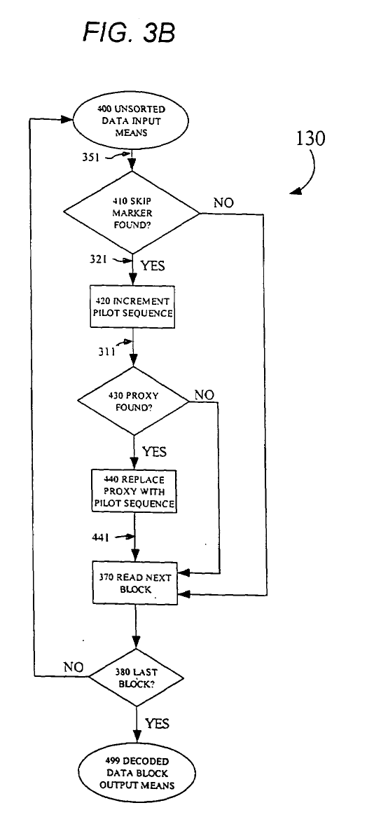

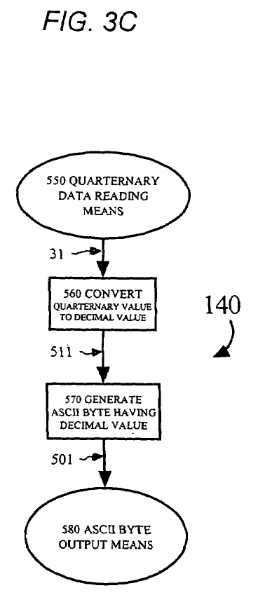

FIG. 3A is a diagram of the first decompression stage of the present invention.

FIG. 3B is a diagram of the second decompression stage of the present invention.

FIG. 3C is a diagram of the final decompression stage of the present invention.

### Reference Numerals In Drawings

| | | | |
|---|---|---|---|
| 20 | User Data File | 21 | User Data |
| 30 | Quarternary Numeral Conversion Process | 31 | Quarternary Numeralized Data |
| 40 | ISSR Encoder | 41 | ISSR Encoded Data |
| 50 | Block Sorting Transform | 51 | Columnar Data |
| 60 | Output to Compression Engine | 120 | Input from Decompressor |
| 130 | Block Unsorting Transform | 131 | Unsorted Data |
| 140 | ISSR Decoder | 141 | ISSR Decoded Data |
| 150 | Quarternary Numeral Reversal Process | 160 | Reproduced User Data |
| 300 | Quarternary Data Input Means | 310 | Pilot Sequence Incrementing Means #1 |
| 311 | Pilot Value | 320 | Skip Value Incrementing Means |
| 321 | Skip Value | 330 | Sequence Finding Means |
| 331 | Proxy Value | 340 | Maximum Skip Checking Means |
| 350 | Skip Marker Writing Means | 351 | Skip-Marked Data |
| 360 | Proxy Substitution Means | 361 | Proxy-Substituted Data |
| 370 | Next Block Reading Means | 380 | Last Block Checking Means |
| 399 | Encoded Block Output Means | 410 | Skip Marker Finding Means |
| 400 | Unsorted Data Input Means | 430 | Proxy Finding Means |
| 420 | Pilot Sequence Incrementing Means #2 | 441 | Proxy-Removed Data |
| 440 | Pilot Sequence Restoration Means | 500 | ASCII Byte-Reading Means |
| 499 | Decoded Block Output Means | 510 | Decimal Value Determination Means |
| 501 | ASCII Data | 520 | Decimal to Quarternary Conversion Means |
| 511 | Decimal Data | 550 | Quarternary Data Reading Means |
| 530 | Quarternary Data Output Means | 570 | ASCII Byte Generating Means |
| 560 | Quarternary to Decimal Conversion Means | 600 | Encoded Data Reading Means |
| 580 | ASCII Byte Output Means | 611 | Rotated Data |
| 610 | Data Rotation Means | 621 | Sorted Data |
| 620 | Rotated Data Sorting Means | 660 | Data Column Reproduction Means |
| 630 | Data Column Output Means | 680 | Rotation Reversing Means |
| 670 | Sort Reversing Means | | |
| 699 | Unsorted Data Output Means | | |

### DETAILED DESCRIPTION

FIG. 1A illustrates a preferred embodiment of the compression enhancing process of the present invention. User Data File 20 composed of User Data 21 is input to Quarternary Numeral Conversion Process 30 which converts the decimal values of the input bytes into quarternary (Base-4) numeral bytes. Quarternary Numeralized Data 31 is then sent to ISSR Encoder 40 which performs an incrementally successive search and replace of multi-byte strings in Quarternary Numeralized Data 31 with single-byte proxy values. ISSR Encoded Data 41 is then sent to Block Sorting Transform 50, which performs a block sort of the ISSR Encoded Data 41, and outputs Columnar Data 51 as output to Compression Engine 60. Compression Engine 60 can be any one of several compression algorithms known in the art, so its operation need not be reiterated here.

FIG. 1B illustrates a preferred embodiment of the overall decompression process of the present invention. Columnar Data 51 is read as input from Decompressor 120 and sent to Block Unsorting Transform 130, where it is unsorted. Unsorted Data 131 is then sent to ISSR Decoder 140 which replaces the single-byte proxy values with the original quarternary numeral strings. ISSR Decoded Data 141 is then sent to Quarternary Numeral Reversal Process 150, which converts the quarternary numeral strings into ASCII data bytes having an equivalent decimal value. Reproduced User Data 160, composed of ASCII Data 501, is then returned to the user.

FIG. 2A illustrates a preferred embodiment of Quarternary Numeral Conversion Process 30. ASCII Data 501 from ASCII Byte Reading Means 500 is input to Decimal Value Determination Means 510. Decimal Value Determination Means 510 generates Decimal Data 511 by determining the decimal value of each byte of ASCII Data 501 that is input. Decimal Data 511 is then sent to Decimal to Quarternary Conversion Means 520. Decimal to Quarternary Conversion Means 520 converts two-digit decimal data into four-digit quarternary data. Once converted, Quarternary Numeralized Data 31 is then output by Quarternary Data Output Means 530 to ISSR Encoder 40.

FIG. 2B illustrates a preferred embodiment of ISSR Encoder 40. Quarternary Data Input Means 300 inputs Quarternary Numeralized Data 31 to Pilot Sequence Incrementing Means #1 310. Starting at a predetermined starting value, Sequence Finding Means 330 scans Quarternary Numeralized Data 31 for Pilot Value 311. If Pilot Value 311 is found immediately, it is replaced with a proxy value by Proxy Substitution Means 360, at which point ISSR Encoder 40 proceeds to read the next block of Quarternary Numeralized Data 31 using Next Block Reading Means 370. If Pilot Value 311 is not immediately found, Maximum Skip Checking Means 340 determines whether or not the maximum number of skips have occurred. If so, Skip Marker Writing Means 350 inserts a symbol into the data stream indicating the maximum number of allowable skips has occurred, at which point Next Block Reading Means 370 proceeds to read the next block of Quarternary Numeralized Data 31. If the maximum number of skips has not occurred, Skip Value Incrementing Means 320 increments Skip Value 321 and instructs Pilot Sequence Incrementing Means #1 310 to also increment Pilot Value 311. Sequence Finding Means 330 then looks for the new Pilot Value 311. This continues until either Pilot Value 311 is located within the block, or until Skip Value 321 is equal to the maximum predetermined allowable number of skips. In either case, when Next Block Reading Means 370 proceeds to read the next block of Quarternary Numeralized Data 31, it first communicates with Last Block Checking Means 380 to see if all blocks of Quarternary Numeralized Data 31 have been read. If so, Encoded Block Output Means 399 outputs ISSR Encoded Data 41 to Block Sorting Transform 50 (FIG. 1A). Otherwise, ISSR Encoder 40 performs an internal loop back to Pilot Sequence Incrementing Means #1 310, increments Pilot Value 311, and continues searching for pilot sequences in the Quarternary Numeralized Data 31.

FIG. 2C illustrates a preferred embodiment of Block Sorting Transform 50. Encoded Data Reading Means 600 accepts ISSR Encoded Data 41 from ISSR Encoder 40. Data Rotation Means 610 rotates the ISSR Encoded Data 41 into an array according to data rotating principles well known in the art. Rotated Data 611 is then sent to Rotated Data Sorting Means 620, where it is sorted numerically. Sorted Data 621 is sent to Data Column Output Means 630, which sends Columnar Data 51 as output to Compression Engine 60.

FIG. 3A illustrates a preferred embodiment of Block Unsorting Transform 130. Columnar Data 51 is read as input from Decompressor 120. Columnar Data 51 is then sent to Data Column Reproduction Means 660 which reproduces Sorted Data 621 according to principles well known in the art. Sorted Data 621 is sent to Sort Reversing Means 670, which reverses the sorting according to principles well known in the art, and outputs Rotated Data 611 to Rotation Reversing Means 680. Rotation Reversing Means 680 reverses the data rotations according to principles well known in the art to produce Unsorted Data 131. Unsorted Data Output Means 699 outputs the Unsorted Data 131 to ISSR Decoder 140.

FIG. 3B illustrates a preferred embodiment of ISSR Decoder 140. ISSSR Decoder 140 reads a block of Skip-Marked Data 351 from Unsorted Data Input Means 400. Beginning with the first predetermined Pilot Sequence, Skip Marker Finding Means 410 searches for a Skip Value 321. If Skip Value 321 is found, Pilot Sequence Incrementing Means #2 420 increments Pilot Value 311 to the next predetermined value. This continues until Proxy Value 331 is found by Proxy Finding Means 430, at which time Pilot Sequence Restoration Means 440 replaces the Proxy Value 331 with the current Pilot Value 311, outputs Proxy-Removed Data 441, and proceeds to read the next block of Skip-Marked Data 351. If Proxy Value 331 is not found in the current block of Skip-Marked Data 351, ISSSR Decoder 140 proceeds to read the next block of Skip-Marked Data 351. If Skip Value 321 is not found in the current block of Skip-Marked Data 351, ISSSR Decoder 140 proceeds to read the next block of Skip-Marked Data 351. At each iteration of this process, Last Block Checking Means 380 determines if ISSSR Decoder 140 has reached the last block of Skip-Marked Data 351. If so, the entire block of Skip-Marked Data 351 has been decoded and is output by Decoded Block Output Means 499 to Quarternary Numeral Reversal Process 150 (FIG. 3C). If Last Block Checking Means 380 determines that ISSSR Decoder 140 has not decoded every block of Skip-Marked Data 351, the above process is repeated until the entire block of Skip-Marked Data 351 is decoded.

FIG. 3C illustrates a preferred embodiment of Quarternary Numeral Reversal Process 150. Quarternary Data Reading Means 550 reads Quarternary Numeralized Data 31 from ISSR Decoder 140. Each group of quarternary numeral bytes is converted into a decimal value by Quarternary to Decimal Conversion Means 560, which then outputs Decimal Data 511. ASCII Byte Generating Means 570 accepts Decimal Data 511 and converts the decimal values into ASCII Data 501. ASCII Byte Output Means 580 outputs ASCII Data 501 as lossless, Reproduced User Data 160 (FIG. 1B).

### Advantages

From the description above, a number of advantages of the present invention become evident to those skilled in the art:
(a) The present invention provides a method and system of enhancing data compression whose effectiveness is not dependent on the type of data being compressed,
(b) The present invention provides a method and system of enhancing data compression which is highly cost-effective, in that it significantly reduces bandwidth, memory, and data storage requirements,
(c) The present invention provides a method and system of enhancing data compression with a low computational expense so that it can compress and decompress data in real-time,
(d) The present invention provides a method and system of enhancing data compression in which the compressed data uses significantly less bandwidth, storage space, and memory than the raw data,
(e) The present invention provides a method and system of enhancing data compression that is computationally inexpensive while achieving high compression efficiency.

### Operation—FIGS. 1A, 1B

The manner in which the present invention functions during compression involves receiving as input a block or stream of User Data 21, converting User Data 21 into Quarternary Data 31 by Quarternary Numeral Conversion Process 30, encoding Quarternary Data 31 into ISSR Encoded Data 41 by ISSR Encoder 40, block sorting ISSR Encoded Data 41 by Block Sorting Transform 50, and outputting Columnar Data 51 to Compression Engine 60.

In addition, the manner in which the present invention functions during decompression involves receiving Columnar Data 51 as input from Decompressor 120, unsorting Columnar Data 51 into Unsorted Data 131 by Block Unsorting Transform 130, decoding Unsorted Data 131 into ISSR Decoded Data 141 by ISSR Decoder 140, reversing ISSR Decoded Data 141 into ASCII Data 501 by Quarternary Numeral Reversal Process 150, and outputting lossless Reproduced User Data 160.

### Conclusion, Ramifications, and Scope

Accordingly, the reader will see that the present invention is a method and system of enhancing data compression and decompression which is substantially insensitive to the type of data it is compressing, and therefore is a content-independent data compression enhancement method and system. The inventive method and system are computationally inexpensive, cost effective, and can operate in real-time.

Although the description above contains many specificities, these should not be construed as limiting the scope of this invention but as merely providing illustrations of some of the presently preferred embodiments thereof.

Thus the scope of this invention should be determined by the appended claims and their legal equivalents, rather than by the examples given.

We claim:

1. A method of preparing computer data to make it more compressible, comprising:
A numeralizing step, wherein the bits of raw user data are converted into a string of ASCII numeral bytes, and
A pilot sequence generating step, wherein a predetermined sequence of said ASCII numeral bytes are chosen as a beginning pilot sequence value, and said beginning pilot sequence value is incremented by a predetermined amount to arrive at the next pilot sequence value, said next pilot sequence value being incremented successively until a predetermined ending pilot sequence value is reached, and
A proxy value generating step, wherein a predetermined value is chosen as a replacement for any of said pilot sequence values, and
A pilot sequence replacement step, wherein said string of ASCII numeral bytes are scanned from beginning to end, while each said pilot sequence is removed from said ASCII numeral bytes and replaced with said proxy value.

2. A system of enhancing compression of computer data, comprising:
A numeralizing step, wherein the bits of raw user data are converted into a string of ASCII numeral bytes, and
A pilot sequence generating step, wherein a predetermined sequence of said ASCII numeral bytes are chosen as a beginning pilot sequence value, and said beginning pilot sequence value is incremented by a predetermined amount to arrive at the next pilot sequence value, said next pilot sequence value being incremented successively until a predetermined ending pilot sequence value is reached, and
A proxy value generating step, wherein a predetermined value is chosen as a replacement for any of said pilot sequence values, and
A pilot sequence replacement step, wherein said string of ASCII numeral bytes are scanned from beginning to end, while each said pilot sequence is removed from said ASCII numeral bytes and replaced with said proxy value.

3. A method of content-independent lossless data compression, comprising:
A numeralizing step, wherein the bits of raw user data are converted into a string of ASCII numeral bytes, and
A pilot sequence generating step, wherein a predetermined sequence of said ASCII numeral bytes are chosen as a beginning pilot sequence value, and said beginning pilot sequence value is incremented by a predetermined amount to arrive at the next pilot sequence value, said next pilot sequence value being incremented successively until a predetermined ending pilot sequence value is reached, and
A proxy value generating step, wherein a predetermined value is chosen as a replacement for any of said pilot sequence values, and
A pilot sequence replacement step, wherein said string of ASCII numeral bytes are scanned from beginning to end, while each said pilot sequence is removed from said ASCII numeral bytes and replaced with said proxy value.

4. A method of reducing memory, storage, and communication bandwidth requirements, comprising:
A numeralizing step, wherein the bits of raw user data are converted into a string of ASCII numeral bytes, and
A pilot sequence generating step, wherein a predetermined sequence of said ASCII numeral bytes are chosen as a beginning pilot sequence value, and said beginning pilot sequence value is incremented by a predetermined amount to arrive at the next pilot sequence value, said next pilot sequence value being incremented successively until a predetermined ending pilot sequence value is reached, and
A proxy value generating step, wherein a predetermined value is chosen as a replacement for any of said pilot sequence values, and
A pilot sequence replacement step, wherein said string of ASCII numeral bytes are scanned from beginning to end, while each said pilot sequence is removed from said ASCII numeral bytes and replaced with said proxy value.
